(19) United States
(12) Patent Application Publication
(10) Pub. No.: US 2026/0370221 A1
(43) Pub. Date: Nov. 19, 2026

(54) Driving Apparatus for SIC-MOSFET Device

(71) Applicant: Siemens Aktiengesellschaft, München (DE)

(72) Inventors: Na Zhao, Tianjin (CN); Xu Bing Qi, Tianjin (CN)

(73) Assignee: Siemens Aktiengesellschaft, München (DE)

(21) Appl. No.: 19/133,604

(22) PCT Filed: Nov. 29, 2022
(86) PCT No.: PCT/CN2022/135127

§ 371 Date: May 28, 2025

(51) Int. Cl. H03K 17/0812; H02M 1/00; H02M 1/08; H02M 1/32; H03K 7/08; H03K 17/16; H03K 19/14

(52) U.S. Cl. CPC H03K 17/08122; H02M 1/0006; H02M 1/08; H02M 1/32; H03K 7/08; H03K 17/162; H03K 19/14; H03K 2217/0036; H03K 2217/0081

(57) ABSTRACT

Teachings of the present disclosure include driving apparatus for a SiC-MOSFET device. An example includes: a power source conditioning circuit; an independent driving power source module connected to the power source conditioning circuit; and a driver connected to the independent driving power source module. The power source conditioning circuit connects a preset DC power source and converts power output from the preset DC power source into supply power needed by the independent driving power source module. The independent driving power source module corresponds, one to one, to a SiC-MOSFET device. The independent driving power source module provides output to the driver, driving power needed by the corresponding SiC-MOSFET device. The driver connects the SiC-MOSFET device, providing the driving power from the independent driving power source module into the corresponding SiC-MOSFET device, and controlling turn-on and turn-off of the SiC-MOSFET device.

### CROSS-REFERENCE TO RELATED APPLICATIONS

This application is a U.S. National Stage Application of International Application No. PCT/CN2022/135127 filed Nov. 29, 2022, which designates the United States of America, the contents of which are hereby incorporated by reference in their entirety.

### TECHNICAL FIELD

The present disclosure relates to semiconductor technology. Various embodiments of the teachings herein include methods and/or driving apparatus for a SiC-MOSFET device.

### BACKGROUND

A SiC-MOSFET device, i.e. silicon carbide-metal oxide semiconductor field effect transistor, is a power device. Now, the SiC-MOSFET device is more widely used than ever. However, there is not a driving apparatus for driving the SiC-MOSFET device. Therefore, it is necessary to provide a driving apparatus for the SiC-MOSFET device.

### SUMMARY

In some embodiments of the teachings of the present disclosure, a driving apparatus for a SiC-MOSFET device comprises a power source conditioning circuit, at least one independent driving power source module connected with the power source conditioning circuit, and a driver connected with the at least one independent driving power source module, wherein the power source conditioning circuit is used for connecting a preset DC power source and converting power output from the preset DC power source into supply power needed by each independent driving power source module; the at least one independent driving power source module corresponds, one to one, to at least one SiC-MOSFET device, each independent driving power source module is used for outputting to the driver driving power, which is needed by the SiC-MOSFET device corresponding to the driving independent power source, after receiving the supply power; and the driver is used for connecting the at least one SiC-MOSFET device, outputting the driving power, which is output by each independent driving power source module, into the SiC-MOSFET device corresponding to the independent driving power source module, and controlling turn-on and turn-off of each SiC-MOSFET device.

In some embodiments, the driving apparatus further comprises: a controlling chip, used for sending a driving signal to a logic conditioning circuit; and the logic conditioning circuit, connected to the controlling chip and the driver, respectively, used for receiving the driving signal sent from the controlling chip, and sending the driving signal to the driver such that the driver controls turn-on and turn-off of the SiC-MOSFET device.

In some embodiments, the driving apparatus further comprises: a pulse width modulation circuit, connected to the controlling chip, used for outputting a pulse signal; wherein accordingly, the controlling chip is used for generating the driving signal according to the pulse signal output by the pulse width modulation circuit.

In some embodiments, the driver is further used for sending an error signal to the logic conditioning circuit when any SiC-MOSFET device is detected to be in an abnormal state; wherein accordingly, the logic conditioning circuit is further used for sending the error signal to the controlling chip, after receiving the error signal, such that the controlling chip controls the pulse width modulation circuit to stop outputting the pulse signal.

In some embodiments, the abnormal state comprises an overcurrent state, a desaturation state, an undervoltage state or a short circuit state.

In some embodiments, the controlling chip and the logic conditioning circuit are connected by an optical fiber therebetween; the logic conditioning circuit comprises: an isolation optical fiber input module, a logic controlling module and an isolation optical fiber output module; wherein: the isolation optical fiber input module is used for converting the driving signal in the form of optical signal, which is output by the controlling chip, into the driving signal in the form of electrical signal, and sending the driving signal in the form of electrical signal to the logic controlling module; the logic controlling module is used for sending the driving signal in the form of electrical signal to the driver; the logic controlling module is further used for receiving the error signal in the form of electrical signal sent by the driver, and sending the error signal in the form of electrical signal to the isolation optical fiber output module; and the isolation optical fiber output module is used for converting the error signal in the form of electrical signal into the error signal in the form of optical signal, and sending the error signal in the form of optical signal to the controlling chip.

In some embodiments, the driver is a grid electrode driver of the type of capacitor isolation.

In some embodiments, the driver comprises a first protection circuit and a driving module; wherein: the first protection circuit is used for: when a source-drain voltage of any SiC-MOSFET device is detected to reach a preset value, determining that the SiC-MOSFET device is in a desaturation state, and sending a notification signal to the driving module; and the driving module is used for: when receiving the notification signal, controlling the SiC-MOSFET device to turn off.

In some embodiments, the first protection circuit comprises a current source, a voltage source, a first diode, a first resistor, a blanking capacitor and a comparator; wherein: the current source is connected to an in-phase input end of the comparator, one end of the first resistor and one end of the blanking capacitor, respectively, another end of the first resistor is connected to a positive electrode of the first diode, a negative electrode of the first diode is connected to the drain electrode of each SiC-MOSFET device, another end of the blanking capacitor is connected to the source electrode of each SiC-MOSFET device; the source electrode of each SiC-MOSFET device is grounded; the voltage source is connected with a reversed-phase input end of the comparator; an output end of the comparator is connected with the driving module, and the comparator is used for sending the notification signal to the driving module when a voltage value at the in-phase input end is higher than that at the reversed-phase input end; and wherein, the voltage value at the in-phase input end is a sum of a drain-source voltage of the SiC-MOSFET device, a voltage drop of the current source on the first diode and another voltage drop of the current source on the first resistor; the voltage value at the reversed-phase input end is a voltage value output by the voltage source, which is a preset desaturation voltage value.

In some embodiments, the driver further comprises a controlling module, the controlling module comprises a second resistor, a third resistor and a second diode; wherein one end of the second resistor and a negative electrode of the second diode are connected with a driving signal output end of the driving module, another end of the second resistor is connected with a grid electrode of each SiC-MOSFET device; one end of the third resistor is connected with a positive electrode of the second diode, another end of the third resistor is connected with the grid electrode of each SiC-MOSFET device; and wherein accordingly, the driving module is used for: outputting a first voltage, which is a positive voltage, causes the second diode to be in a cut-off state and causes the SiC-MOSFET device to turn on, when the driving signal is in high level; and outputting a second voltage, which is a negative voltage, causes the second diode to be in a turn-on state and cause the SiC-MOSFET device to turn off, when the driving signal is in low level.

### BRIEF DESCRIPTION OF THE DRAWINGS

In order to explain the technical solutions in the embodiments of the present disclosure more clearly, the figures necessary to be used for description in the embodiments or in the prior art will be briefly introduced as below. The figures for the description below are for some embodiments but are not in any way limiting the scope of the disclosure. In the drawings:

FIG. 1 is a diagram for connection between an example driving apparatus and an example SiC-MOSFET device incorporating teachings of the present disclosure;

FIG. 2 is a diagram for connection between an example driving apparatus and an example SiC-MOSFET device incorporating teachings of the present disclosure;

FIG. 3 is a structural diagram of a logic conditioning circuit incorporating teachings of the present disclosure; and

FIG. 4 is a circuit diagram of a driver incorporating teachings of the present disclosure.

### REFERENCE NUMERALS

| | |
|---|---|
| power source conditioning circuit | 110 |
| independent driving power source module | 120 |
| driver | 130 |
| SiC-MOSFET device | 200 |
| logic conditioning circuit | 140 |
| controlling chip | 150 |
| pulse width modulation circuit | 160 |
| isolation optical fiber input module | 142 |
| logic controlling module | 141 |
| isolation optical fiber output module | 143 |
| first protection circuit | 131 |
| driving module | 132 |
| controlling module | 133 |
| drain electrode of SiC-MOSFET device | D |
| source electrode of SiC-MOSFET device | S |
| grid electrode of SiC-MOSFET device | G |
| comparator | E1 |
| current source | A |
| voltage source | V |
| first resistor | R1 |
| first diode | D1 |
| blanking capacitor | C1 |
| second resistor | R2 |
| third resistor | R3 |
| second diode | D2 |
| desaturation protection end | DESAT |
| driving signal output end | OUT |

### DETAILED DESCRIPTION

In some embodiments, the driving apparatus comprises a power source conditioning circuit, at least one independent driving power source module connected with the power source conditioning circuit, and a driver connected with the at least one independent driving power source module; the power source conditioning circuit is used for connecting a preset DC power source and converting power output from the preset DC power source into supply power needed by each independent driving power source module; each independent driving power source module is used for outputting to the driver driving power, which is needed by the SiC-MOSFET device corresponding to the driving independent power source, after receiving the supply power; the driver is used for outputting the driving power, which is output by each independent driving power source module, into the SiC-MOSFET device corresponding to the independent driving power source module, and controlling turn-on and turn-off of each SiC-MOSFET device. As can be seen, in the embodiment(s) of the present invention, a suitable driving apparatus is provided for the SiC-MOSFET device wherein each SiC-MOSFET device is equipped with one independent driving power source module so as to provide the corresponding driving power for each SiC-MOSFET device, and the independent driving power source modules can obtain the needed supply power from the power source conditioning circuit such that the driving power currents/voltages of various SiC-MOSFET devices come from mutually independent and isolated branch paths, without any mutual influence, which can reduce mutual interference between the SiC-MOSFET devices to a certain degree.

In some embodiments, the driver is a grid electrode driver of the type of capacitor isolation. As the grid electrode driver of the type of capacitor isolation itself has a relatively high common mode transient immunity (CMTI), it is quite suitable for driving high-speed SiC-MOSFET devices. Moreover, as the SiC-MOSFET device has a feature of very quick turning on/off speed, the SiC-MOSFET device is prone to be interfered by various factors such that the controlling of turning on/off of the SiC-MOSFET device is affected. The grid electrode driver of the type of capacitor isolation is integrated with various protection modules and can perform respective operations in time when the SiC-MOSFET device becomes abnormal due to interference or other reasons, thus reducing influence by various interference factors on controlling of turning on/off of the SiC-MOSFET device.

In some embodiments, the driver comprises a first protection circuit, used for: when a source-drain voltage of any SiC-MOSFET device is detected to reach a preset value, determining that the SiC-MOSFET device is in a desaturation state, and sending a notification signal to the driving module; the driving module is used for: when receiving the notification signal, controlling the SiC-MOSFET device to turn off. As can be seen, with the first protection circuit and the driving module in the driver, the desaturation protection function can be achieved.

In some embodiments, the first protection circuit comprises a current source, a voltage source, a first diode, a first resistor, a blanking capacitor and a comparator. When the drain-source voltage of the SiC-MOSFET device reaches the above-described preset value, the sum of the drain-source voltage of the SiC-MOSFET device, a voltage drop of the current source on the first diode and another voltage drop of the current source on the first resistor will be higher than the voltage provided by the voltage source. At this time, the comparator will output the notification signal to the driving module, and in turn the driving module controls the SiC-MOSFET device to turn off. As can be seen, a specific structure of the first protection circuit is provided herein. In such specific structure, it is possible to monitor the drain-source voltage of the SiC-MOSFET device in real time. Once the drain-source voltage of the SiC-MOSFET device reaches the preset value, the comparator will inform the driving module, and in turn the SiC-MOSFET device is turned off, thus performing desaturation protection operation in time.

In some embodiments, the driver further comprises a controlling module which comprises a second resistor, a third resistor and a second diode. When it is necessary for the SiC-MOSFET device to be in the turn-on state, the driving module will output a first voltage, which is a positive voltage. The first voltage is higher than the grid electrode voltage of the SiC-MOSFET device and can cause the SiC-MOSFET device to turn on. Moreover, the first voltage can cause the second diode to be in the cut-off state. At this time, the branch path in the controlling module where the second resistor is disposed is turned on, and there is no current passing through the branch path where the third resistor is disposed. When it is necessary for the SiC-MOSFET device to be in the turn-off state, the driving module will output a second voltage which is a negative voltage. The second voltage is lower than the grid electrode voltage of the SiC-MOSFET device and thus causes the SiC-MOSFET device to turn off. Moreover, the second voltage causes the second diode to turn on, and thus there is a current passing through the branch path where the third resistor is disposed. Certainly, at this time, there is also a current passing through the branch path where the second resistor is disposed. In this case, the total resistance of these two parallel branch paths is lower than the resistance value of the second resistor. As can be seen, when it is necessary to turn off the SiC-MOSFET device, with the grid electrode having a relatively low resistance, the consumption for turning on/off can be reduced. In a circuit comprising a relatively large number of SiC-MOSFET devices, the total consumption of the driving apparatus can be significantly reduced by reduction in consumption for turning on/off.

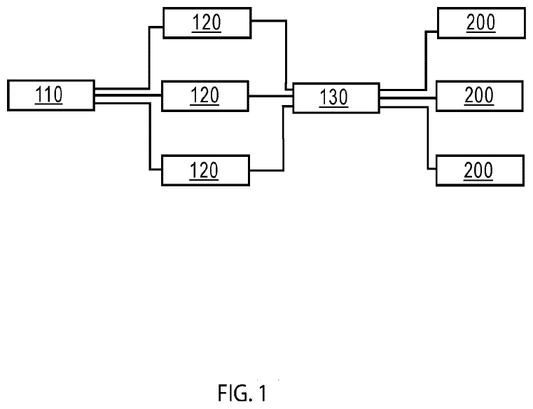

FIG. 1 shows an example driving apparatus incorporating teachings of the present disclosure. The example comprises: a power source conditioning circuit 110, at least one independent driving power source module 120 connected with the power source conditioning circuit 110, and a driver 130 connected with the at least one independent driving power source module 120, wherein:
the power source conditioning circuit 110 is used for connecting a preset DC power source and converting power output from the preset DC power source into supply power needed by each independent driving power source module 120;
the at least one independent driving power source module 120 corresponds, one to one, to at least one SiC-MOSFET device 200, each independent driving power source module 120 is used for outputting to the driver 130 driving power, which is needed by the SiC-MOSFET device 200 corresponding to the driving independent power source 120, after receiving the supply power; and
the driver 130 is used for connecting the at least one SiC-MOSFET device 200, outputting the driving power, which is output by each independent driving power source module 120, into the SiC-MOSFET device 200 corresponding to the independent driving power source module, and controlling turn-on and turn-off of each SiC-MOSFET device 200.

Herein, the SiC-MOSFET device is Silicon Carbide-Metal Oxide Semiconductor Field Effect Transistor and is a power device. Herein, the power source conditioning circuit functions to convert a DC power output from one preset DC power source into at least one supply power. The supply power currents/voltages may be same or may be different, depending on requirements of the independent driving power source modules. The supply power current/voltages are independent with respect to one another and are supplied to respective independent driving power source modules.

Herein, each independent driving power source module operates at the supply power and outputs the corresponding driving power to the driver. The driving power current/voltages output by the independent driving power source modules may be same or may be different, depending on requirements of the SiC-MOSFET devices. The independent driving power source modules are mutually independent and isolated, without any mutual influence, providing the driving power current/voltages to the respective SiC-MOSFET devices.

In order to enable whole controlling of the independent driving power sources, the driving power output by each independent driving power source module is first input into the driver, then the driver supplies the driving power into the SiC-MOSFET device, providing the driving power for the SiC-MOSFET device. For example, if in a situation, one of the SiC-MOSFET devices is problematic while other SiC-MOSFET device(s) can still work normally, in this case, it may be not necessary for the driver to provide the driving power to the problematic SiC-MOSFET device.

The SiC-MOSFET device will enter various states, such as turn-off, turn-on, etc., only when it is supplied with the driving power. The controlling of the state of the SiC-MOSFET device is achieved by the driver. As can be seen, the driver mainly functions to supply the driving power, output from the independent driving power source module, into the corresponding SiC-MOSFET device, and to control the states of the SiC-MOSFET device, such as turn-on or turn-off, etc.

When the SiC-MOSFET device is turned off, it does not mean that the SiC-MOSFET device stops operation. When the SiC-MOSFET device is in the state of turn-on or turn-off, it may cause the module(s) connected with the SiC-MOSFET device in the subsequent step(s) to be in different states, thus achieving different functions.

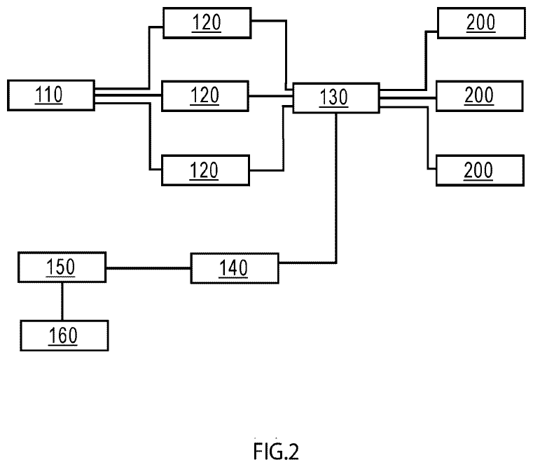

FIG. 2 shows an example driving apparatus may further comprise: a controlling chip 150, used for sending a driving signal to a logic conditioning circuit 140; and the logic conditioning circuit 140, connected to the controlling chip 150 and the driver 130, respectively, used for receiving the driving signal sent from the controlling chip 150 and sending the driving signal to the driver 130 such that the driver 130 controls turn-on and turn-off of the SiC-MOSFET device 200. That is, the driving apparatus comprises the power source conditioning circuit, at least one independent driving power source module, the driver, the controlling chip, and the logic conditioning circuit.

Herein, the controlling chip functions to send the driving signal to the logic conditioning circuit, and the logic conditioning circuit functions to send the driving signal to the driver. Thus, the driver uses the driving signal to control turn-on and turn-off of each SiC-MOSFET device. As can be seen, the controlling chip herein uses the logic conditioning circuit to send the driving signal to the driver. Thus, the operator can use the controlling chip for controlling, thereby deciding when to start sending the driving signal and when to stop sending the driving signal. That is, by providing the controlling chip, it is possible to meet the need of the operator for sending the driving signal according to requirements.

Further, referring to FIG. 2, the driving apparatus may further comprise: a pulse width modulation circuit 160, connected to the controlling chip 150, used for outputting a pulse signal; wherein accordingly, the controlling chip 150 is used for generating the driving signal according to the pulse signal output by the pulse width modulation circuit 160. That is, the controlling chip is connected with a pulse width modulation circuit, i.e. PWM circuit, which can send the pulse signal to the controlling chip. The controlling chip can generate the driving signal according to the pulse signal. For example, in the pulse signal, the high level is 1 and the low level is 0. The controlling chip converts the high level in the pulse signal into a positive voltage and converts the low level in the pulse signal into a negative voltage. Herein, the positive voltage can cause the corresponding SiC-MOSFET device to enter the turn-on state, while the negative voltage can cause the corresponding SiC-MOSFET device to enter the cut-off state. The positive and negative voltages form the driving signal in a sawtooth wave.

For example, in a situation, the operator performs controlling by the controlling chip such that the controlling chip actuates the pulse width modulation circuit to work and thus the pulse width modulation circuit sends the pulse signal. It is also possible to perform controlling by the controlling chip such that the controlling chip controls the pulse width modulation circuit to stop working and thus the pulse width modulation circuit stops sending the pulse signal.

In addition to the external controlling manner(s) by the operator, when there is an abnormal state for the SiC-MOSFET device itself, it is also possible to automatically control the pulse width modulation circuit to stop outputting the pulse signal. In an embodiment, the driver may be further used for sending an error signal to the logic conditioning circuit when any SiC-MOSFET device is detected to be in an abnormal state; wherein accordingly, the logic conditioning circuit is further used for sending the error signal to the controlling chip, after receiving the error signal, such that the controlling chip controls the pulse width modulation circuit to stop outputting the pulse signal.

That is, when any SiC-MOSFET device is detected by the driver to be abnormal, the driver will send an error signal to the logic conditioning circuit. After the logic conditioning circuit receives the error signal, it will send the error signal to the controlling chip. After the controlling chip receives the error signal, it will control the pulse width modulation circuit to stop outputting the pulse signal such that the SiC-MOSFET devices stop working. Herein, the abnormal state may comprise an overcurrent state, a desaturation state, an undervoltage state or a short circuit state.

As can be seen, when any SiC-MOSFET device is abnormal, the SiC-MOSFET devices will be controlled, by the driver, the logic conditioning circuit, the controlling chip, and the pulse width modulation circuit, to stop working, thus preventing the abnormal SiC-MOSFET device(s) from affecting the functions of the modules connected with the SiC-MOSFET device (s) in the subsequent step(s).

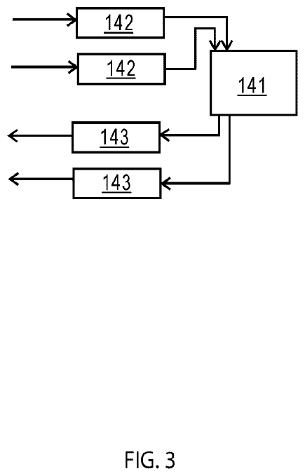

In some embodiments, the controlling chip and the logic conditioning circuit are connected by an optical fiber therebetween. Accordingly, referring to FIG. 3, the logic conditioning circuit may comprise: an isolation optical fiber input module 142, a logic controlling module 141, and an isolation optical fiber output module 143; wherein: the isolation optical fiber input module 142 is used for converting the driving signal in the form of optical signal, which is output by the controlling chip, into the driving signal in the form of electrical signal, and sending the driving signal in the form of electrical signal to the logic controlling module; the logic controlling module 141 is used for sending the driving signal in the form of electrical signal to the driver; the logic controlling module is further used for receiving the error signal in the form of electrical signal sent by the driver, and sending the error signal in the form of electrical signal to the isolation optical fiber output module; and the isolation optical fiber output module 143 is used for converting the error signal in the form of electrical signal into the error signal in the form of optical signal, and sending the error signal in the form of optical signal to the controlling chip.

That is, the logic conditioning circuit comprises an isolation optical fiber input module, a logic controlling module, and an isolation optical fiber output module. The isolation optical fiber input module functions to convert the driving signal in the form of optical signal, which is sent by the controlling chip, into the driving signal in the form of electrical signal. The isolation optical fiber output module functions to convert the error signal in the form of electrical signal, which is sent by the driver, into the error signal in the form of optical signal. As can be seen, the isolation optical fiber input module and the isolation optical fiber output module isolate the optical signal and the electrical signal, and enable conversion therebetween.

Herein, there may be one or more isolation optical fiber input modules, and one isolation optical fiber input module thereof which is in the idle state will be used each time. Also, there may be one or more isolation optical fiber output modules, and one isolation optical fiber output module thereof which is in the idle state will be used each time.

In some embodiments, the driver may be a grid electrode driver of the type of capacitor isolation.

As the operation efficiency of power switch devices becomes higher and higher, from 10 kHz for Si IGBT to 100 kHz for SiC-MOSFET device, there are higher requirements on drivers for power switch devices. As the SiC-MOSFET device has a feature of quick turning on/off speed, if a driver like an optical coupler is used, it is difficult to solve a problem that the common mode transient immunity (i.e. CMTI value) is not sufficiently high, which is very dangerous to high-speed SiC-MOSFET devices. Therefore, in the embodiment(s) of the present invention, the driver uses a grid electrode driver of the type of capacitor isolation. The grid electrode driver of the type of capacitor isolation itself has a relatively high CMTI and it quite suitable for driving high-speed SiC-MOSFET devices.

Moreover, as the SiC-MOSFET device has a feature of quick turning on/off speed, the SiC-MOSFET device is prone to be interfered by various factors such that the controlling of turning on/off of the SiC-MOSFET device is affected. The grid electrode driver of the type of capacitor isolation has an internal protection function, and can perform respective operations in time when the SiC-MOSFET device becomes abnormal, thus reducing influence by various electromagnetic interference cases on controlling of turning on/off of the SiC-MOSFET device.

The grid electrode driver of the type of capacitor isolation is integrated with desaturation protection function, undervoltage protection function, short circuit protection function, overcurrent protection function, gate active tracking protection function, source Miller clamping protection function. With these protection functions, it can be ensured that respective protection operations can be performed in time when the SiC-MOSFET device becomes abnormal.

In a practical situation, it is possible to select a suitable grid electrode driver of the type of capacitor isolation according to some indexes, such as the required driving ability, the required switching frequency and transmission delay in practical applications, CMTI, or the like. According to these indexes, it is possible to select a suitable grid electrode driver of the type of capacitor isolation from various models of grid electrode drivers of the type of capacitor isolation.

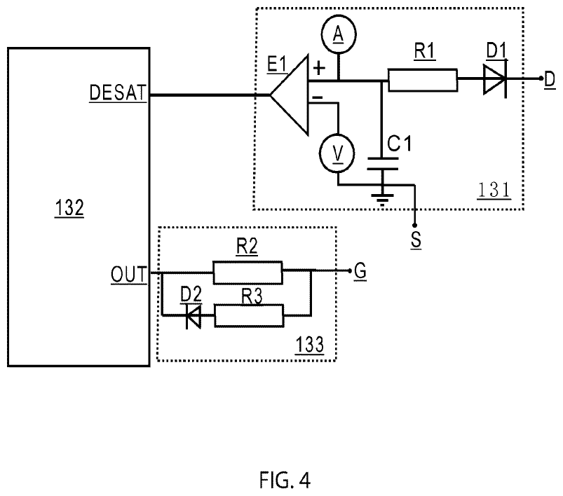

In some embodiments, like that shown in FIG. 4, the driver may comprise a first protection circuit 131 and a driving module 132; wherein: the first protection circuit 131 is used for: when a source-drain voltage of any SiC-MOSFET device 200 is detected to reach a preset value, determining that the SiC-MOSFET device 200 is in a desaturation state, and sending a notification signal to the driving module 132; and the driving module 132 is used for: when receiving the notification signal, controlling the SiC-MOSFET device 200 to turn off.

That is, the driver may use the first protection circuit and the driving module to achieve desaturation protection function. The first protection circuit is connected to source and drain electrodes of the SiC-MOSFET devices, thus testing the source-drain voltage of the SiC-MOSFET device. When the drain-source voltage of any SiC-MOSFET device is higher than the above-described preset value, it may be considered that the SiC-MOSFET device is in the desaturation state. At this time, the driving module is informed by the notification signal, to perform desaturation protection.

For example, for a 300 A/1700V SiC-MOSFET device, in its output characteristic curve, the horizontal ordinate is Vds voltage and the vertical ordinate is Ids current. When the source-drain voltage is about 10V, the output current of the SiC-MOSFET device reaches about 280 A before clamping, and when the source-drain voltage is about 15V, the output current can reach about 700 A, and in this case, it is considered to enter the desaturation state and it is necessary at this time to turn off the SiC-MOSFET device.

Herein, the first protection circuit may be formed in various structure forms. Referring to FIG. 4, an optional structure form is provided below. The first protection circuit 131 may comprise a current source A, a voltage source V, a first diode D1, a first resistor R1, a blanking capacitor C1 and a comparator E1; wherein: the current source A is connected to an in-phase input end of the comparator E1, one end of the first resistor R1 and one end of the blanking capacitor C1, respectively, another end of the first resistor R1 is connected to a positive electrode of the first diode D1, a negative electrode of the first diode D1 is connected to the drain electrode D of each SiC-MOSFET device, another end of the blanking capacitor C1 is connected to the source electrode S of each SiC-MOSFET device; the source electrode S of each SiC-MOSFET device is grounded; the voltage source V is connected with a reversed-phase input end of the comparator; an output end of the comparator E1 is connected with the driving module 132, and the comparator E1 is used for sending the notification signal to the driving module 132 when a voltage value at the in-phase input end is higher than that at the reversed-phase input end; and wherein, the voltage value at the in-phase input end is a sum of a drain-source voltage of the SiC-MOSFET device, a voltage drop of the current source A on the first diode D1 and another voltage drop of the current source A on the first resistor R1; the voltage value at the reversed-phase input end is a voltage value output by the voltage source V, which is a preset desaturation voltage value.

Herein, the comparator E1 sends the notification signal to a desaturation protection end DESAT of the driving module 132. That is, when the drain-source voltage of the SiC-MOSFET device reaches the above-described preset value, the sum of the drain-source voltage of the SiC-MOSFET device, the voltage drop of the current source on the first diode and the voltage drop of the current source on the first resistor will be higher than the voltage provided by the voltage source. At this time, the comparator will output the notification signal to the driving module, and in turn the driving module controls the SiC-MOSFET device to turn off.

Herein, the current source functions to output a constant current which passes through the resistor to generate a voltage drop and passes through the first diode to generate another voltage drop. The sum of these two voltage drops plus the drain-source voltage of the SiC-MOSFET device serves as the input voltage at the in-phase input end of the comparator. Herein, the voltage source functions to provide a reference voltage which is the preset desaturation voltage value. The reference voltage output from the voltage source serves as the input voltage at the reversed-phase input end.

Herein, the comparator functions to compare the input voltage at the in-phase input end with the input voltage at the reversed-phase input end and send a notification signal to the driving module when the input voltage at the in-phase input end is higher than the input voltage at the reversed-phase input end. In turn, the desaturation protection is performed. As can be seen, the desaturation protection function can be achieved by the above manner.

Certainly, the driving module may also generate an error signal and send it to the logic conditioning circuit. In turn, the controlling chip is used to control the pulse width modulation circuit to stop outputting the pulse signal. Other protection functions may be achieve by other protection circuits respectively, which will not described herein in detail.

Further, as shown in FIG. 4, the driver may further comprise a controlling module 133, the controlling module 133 comprises a second resistor R2, a third resistor R3 and a second diode D2; wherein one end of the second resistor R2 and a negative electrode of the second diode D2 are connected with a driving signal output end of the driving module, another end of the second resistor R2 is connected with a grid electrode of each SiC-MOSFET device; one end of the third resistor R3 is connected with a positive electrode of the second diode D2, another end of the third resistor R3 is connected with the grid electrode of each SiC-MOSFET device; and wherein accordingly, the driving module is used for: outputting a first voltage, which is a positive voltage, causes the second diode D2 to be in a cut-off state and causes the SiC-MOSFET device to turn on, when the driving signal is in high level; and outputting a second voltage, which is a negative voltage, causes the second diode D2 to be in a turn-on state and cause the SiC-MOSFET device to turn off, when the driving signal is in low level.

The controlling module is provided between the driving module and the grid electrode of the SiC-MOSFET device. Herein, one end of the second resistor R2 and a negative electrode of the second diode D2 are connected with a driving signal output end OUT of the driving module, and the driving module uses the driving signal output end OUT to output the first voltage and the second voltage.

When it is necessary for the SiC-MOSFET device to be in the turn-on state, the driving module will output a first voltage which is a positive voltage, such as 15 v. The first voltage is higher than the grid electrode voltage of the SiC-MOSFET device and can cause the SiC-MOSFET device to turn on. Moreover, the first voltage can cause the second diode to be in the cut-off state. At this time, the branch path in the controlling module where the second resistor is disposed is turned on, and there is no current passing through the branch path where the third resistor is disposed.

When it is necessary for the SiC-MOSFET device to be in the turn-off state, the driving module will output a second voltage which is a negative voltage, such as −8 v. The second voltage is lower than the grid electrode voltage of the SiC-MOSFET device and thus causes the SiC-MOSFET device to turn off. Moreover, the second voltage causes the second diode to turn on, and thus there is a current passing through the branch path where the third resistor is disposed. Certainly, at this time, there is also a current passing through the branch path where the second resistor is disposed. In this case, the total resistance of these two parallel branch paths is lower than the resistance value of the second resistor.

Herein, the controlling module is provided between the driving module and the grid electrode of the SiC-MOSFET device. When it is necessary to turn off the SiC-MOSFET device, if the grid electrode has a relatively low resistance, the consumption for turning on/off can be reduced. In a circuit comprising a large number of SiC-MOSFET devices, the total consumption of the driving apparatus can be significantly reduced by reduction in consumption for turning on/off.

The description of the same or similar portions of different embodiments can be referred to each other. Each description attempts to emphasize the difference(s) with respect to other embodiment(s). In particular, as the apparatus/device embodiments are substantially similar to the method embodiments, the description thereof is relatively simple, and the description of the method embodiments may be referred to for related portions.

With the above-described specific embodiments, the purposes, technical solutions and beneficial effects of the present disclosure are further explained in detail. The above description is only for specific embodiments of the teachings herein, not for defining the protection scope of the present disclosure. Any variation, equivalent substitution or improvement made based on the technical solutions will fall within the protection scope thereof.

What is claimed is:

1. A driving apparatus for a SiC-MOSFET device, the apparatus comprising:
a power source conditioning circuit;
an independent driving power source module connected to the power source conditioning circuit; and
a driver connected to the independent driving power source module;
wherein
the power source conditioning circuit connects a preset DC power source and converts power output from the preset DC power source into supply power needed by the independent driving power source module;
the independent driving power source module corresponds, one to one, to a SiC-MOSFET device;
the independent driving power source module provides output to the driver, driving power needed by the corresponding SiC-MOSFET device; and
the driver connects the SiC-MOSFET device, providing the driving power from the independent driving power source module into the corresponding SiC-MOSFET device, and controlling turn-on and turn-off of the SiC-MOSFET device.

2. The driving apparatus according to claim 1, further comprising:
a controlling chip to send a driving signal to a logic conditioning circuit; and
the logic conditioning circuit connected to the controlling chip and the driver to receive the driving signal sent from the controlling chip, and send the driving signal to the driver so the driver controls turn-on and turn-off of the SiC-MOSFET device.

3. The driving apparatus according to claim 2, further comprising
a pulse width modulation circuit connected to the controlling chip to deliver a pulse signal;
wherein the controlling chip generates the driving signal according to the pulse signal output from the pulse width modulation circuit.

4. The driving apparatus according to claim 3, the driver sends an error signal to the logic conditioning circuit when any SiC-MOSFET device is detected in an abnormal state; and
the logic conditioning circuit sends the error signal to the controlling chip so the controlling chip controls the pulse width modulation circuit to stop delivering the pulse signal.

5. The driving apparatus according to claim 4, wherein the abnormal state comprises one of: an overcurrent state, a desaturation state, an undervoltage state, or a short circuit state.

6. The driving apparatus according to claim 4, wherein:
the controlling chip and the logic conditioning circuit are connected by an optical fiber therebetween;
the logic conditioning circuit comprises: an isolation optical fiber input module, a logic controlling module, and an isolation optical fiber output module; wherein:
the isolation optical fiber input module converts the driving signal in the form of optical signal from the controlling chip, into the driving signal in the form of electrical signal, and sends the driving signal in the form of electrical signal to the logic controlling module;
the logic controlling module sends the driving signal in the form of electrical signal to the driver;
the logic controlling module receives the error signal in the form of electrical signal sent by the driver, and sends the error signal in the form of electrical signal to the isolation optical fiber output module; and
the isolation optical fiber output module converts the error signal in the form of electrical signal into the error signal in the form of optical signal, and sending the error signal in the form of optical signal to the controlling chip.

7. The driving apparatus according to claim 1, wherein the driver comprises a capacitor isolation grid electrode driver.

8. The driving apparatus according to claim 7, wherein
the driver comprises a first protection circuit and a driving module;
when a source-drain voltage of any SiC-MOSFET device is detected to reach a preset value, the first protection circuit determines that the SiC-MOSFET device is in a desaturation state, and sends a notification signal to the driving module; and
when receiving the notification signal, the driving module controls the SiC-MOSFET device to turn off.

9. The driving apparatus according to claim 8, wherein:
the first protection circuit comprises a current source, a voltage source, a first diode, a first resistor, a blanking capacitor and a comparator;
the current source is connected to an in-phase input end of the comparator, one end of the first resistor and one end of the blanking capacitor, respectively, another end of the first resistor is connected to a positive electrode of the first diode, a negative electrode of the first diode is connected to the drain electrode of each SiC-MOSFET device, another end of the blanking capacitor is connected to the source electrode of each SiC-MOSFET device; the source electrode of each SiC-MOSFET device is grounded;
the voltage source is connected to a reversed-phase input end of the comparator;
an output end of the comparator is connected to the driving module, and the comparator the notification signal to the driving module when a voltage value at the in-phase input end is higher than that at the reversed-phase input end; and
the voltage value at the in-phase input end is a sum of a drain-source voltage of the SiC-MOSFET device, a voltage drop of the current source on the first diode and another voltage drop of the current source on the first resistor; the voltage value at the reversed-phase input end is a voltage value output by the voltage source, which is a preset desaturation voltage value.

10. The driving apparatus according to claim 8, wherein:
the driver further comprises a controlling module with a second resistor, a third resistor and a second diode;
one end of the second resistor and a negative electrode of the second diode are connected to a driving signal output end of the driving module;
another end of the second resistor is connected with a grid electrode of each SiC-MOSFET device;
one end of the third resistor is connected with a positive electrode of the second diode;
another end of the third resistor is connected with the grid electrode of each SiC-MOSFET device; and
the driving module provides a first positive voltage causing the second diode to be in a cut-off state and the SiC-MOSFET device to turn on, when the driving signal is in high level, and provides a second negative voltage causing the second diode to be in a turn-on state and cause the SiC-MOSFET device to turn off, when the driving signal is in low level.
